(19) United States
(12) Patent Application Publication
(10) Pub. No.: US 2025/0142934 A1
(43) Pub. Date: May 1, 2025

(54) SEMICONDUCTOR DEVICE AND METHOD FOR MANUFACTURING SEMICONDUCTOR DEVICE

(71) Applicant: Mitsubishi Electric Corporation, Tokyo (JP)

(72) Inventors: Asuka MATSUYAMA, Tokyo (JP); Noriyuki YABUOSHI, Tokyo (JP); Akie YUTANI, Tokyo (JP)

(73) Assignee: Mitsubishi Electric Corporation, Tokyo (JP)

(21) Appl. No.: 18/911,105

(22) Filed: Oct. 9, 2024

(30) Foreign Application Priority Data
Oct. 26, 2023 (JP) 2023-183706

(51) Int. Cl. H01L 29/43; H01L 21/02; H01L 21/3115; H01L 23/528

(52) U.S. Cl. CPC H10D 64/605; H01L 21/02164; H01L 21/0217; H01L 21/31155; H01L 23/528; H01L 23/5283

(57) ABSTRACT

Provided is a semiconductor device in which deterioration of a gate insulating layer is suppressed. A semiconductor device includes a semiconductor substrate, a gate insulating film, a gate electrode, a first electric wire, and a semiconductive insulating layer. The gate insulating film is formed on the semiconductor substrate. The gate electrode is formed on the semiconductor substrate with the gate insulating film being interposed therebetween. The first electric wire is connected to the gate electrode. The semiconductive insulating layer is connected to at least one of the gate electrode and the first electric wire.

### CROSS REFERENCE TO RELATED APPLICATIONS

This nonprovisional application is based on Japanese Patent Application No. 2023-183706 filed on Oct. 26, 2023 with the Japan Patent Office, the entire contents of which are hereby incorporated by reference.

### BACKGROUND OF THE INVENTION

### Field of the Invention

The present disclosure relates to a semiconductor device and a method for manufacturing a semiconductor device.

### Description of the Background Art

In a process of manufacturing a semiconductor device, an amorphous carbon film that releases a charge to a semiconductor substrate is formed to suppress charging of a gate insulating layer (see, for example, Japanese Patent Laying-Open No. 7-245390). By forming such an amorphous carbon film, charge-up is suppressed during ion implantation in the process of manufacturing the semiconductor device.

### SUMMARY OF THE INVENTION

However, the amorphous carbon film as described above is removed after the ion implantation. Accordingly, in a step after the ion implantation, the gate insulating layer may be charged, and the gate insulating layer may be deteriorated.

The present disclosure has been made in order to solve the aforementioned problem, and an object of the present disclosure is to provide a semiconductor device in which deterioration of a gate insulating layer is suppressed.

A semiconductor device according to the present disclosure includes a semiconductor substrate, a gate insulating film, a gate electrode, a first electric wire, and a semiconductive insulating layer. The gate insulating film is formed on the semiconductor substrate. The gate electrode is formed on the semiconductor substrate with the gate insulating film being interposed therebetween. The first electric wire is connected to the gate electrode. The semiconductive insulating layer is connected to at least one of the gate electrode and the first electric wire.

A method for manufacturing a semiconductor device according to the present disclosure includes preparing a semiconductor substrate, forming a first semiconductive insulating layer on the semiconductor substrate, and rotating the semiconductor substrate after forming the first semiconductive insulating layer.

The foregoing and other objects, features, aspects, and advantages of the present invention will become more apparent from the following detailed description of the present invention when taken in conjunction with the accompanying drawings.

### BRIEF DESCRIPTION OF THE DRAWINGS

FIG. 1 is a schematic cross sectional view of a semiconductor device in accordance with a first embodiment.

FIG. 2 is a schematic plan view of the semiconductor device in accordance with the first embodiment.

FIG. 3 is a flowchart of a method for manufacturing the semiconductor device in accordance with the first embodiment.

FIG. 4 is a schematic cross sectional view showing one step of the method for manufacturing the semiconductor device in accordance with the first embodiment.

FIG. 5 is a schematic cross sectional view showing one step of the method for manufacturing the semiconductor device in accordance with the first embodiment.

FIG. 6 is a schematic cross sectional view showing one step of the method for manufacturing the semiconductor device in accordance with the first embodiment.

FIG. 7 is a schematic cross sectional view showing one step of the method for manufacturing the semiconductor device in accordance with the first embodiment.

FIG. 8 is a schematic cross sectional view showing one step of the method for manufacturing the semiconductor device in accordance with the first embodiment.

FIG. 9 is a schematic cross sectional view showing one step of the method for manufacturing the semiconductor device in accordance with the first embodiment.

FIG. 10 is a schematic cross sectional view showing one step of the method for manufacturing the semiconductor device in accordance with the first embodiment.

FIG. 11 is a schematic cross sectional view showing one step of the method for manufacturing the semiconductor device in accordance with the first embodiment.

FIG. 12 is a schematic cross sectional view showing one step of the method for manufacturing the semiconductor device in accordance with the first embodiment.

FIG. 13 is a schematic cross sectional view showing one step of the method for manufacturing the semiconductor device in accordance with the first embodiment.

FIG. 14 is a schematic cross sectional view showing one step of the method for manufacturing the semiconductor device in accordance with the first embodiment.

FIG. 15 is a schematic cross sectional view showing one step of the method for manufacturing the semiconductor device in accordance with the first embodiment.

FIG. 16 is a schematic cross sectional view showing one step of the method for manufacturing the semiconductor device in accordance with the first embodiment.

FIG. 17 is a schematic cross sectional view of a semiconductor device in accordance with a second embodiment.

FIG. 18 is a flowchart of a method for manufacturing the semiconductor device in accordance with the second embodiment.

FIG. 19 is a schematic cross sectional view showing one step of the method for manufacturing the semiconductor device in accordance with the second embodiment.

FIG. 20 is a schematic cross sectional view of a semiconductor device in accordance with a third embodiment.

FIG. 21 is a schematic cross sectional view of a semiconductor device in accordance with a fourth embodiment.

### DESCRIPTION OF THE PREFERRED EMBODIMENTS

Hereinafter, embodiments of the present disclosure will be described. It should be noted that, unless specified otherwise, identical or corresponding parts in the drawings below will be designated by the same reference numerals, and the description thereof will not be repeated.

### First Embodiment

### Configuration of Semiconductor Device

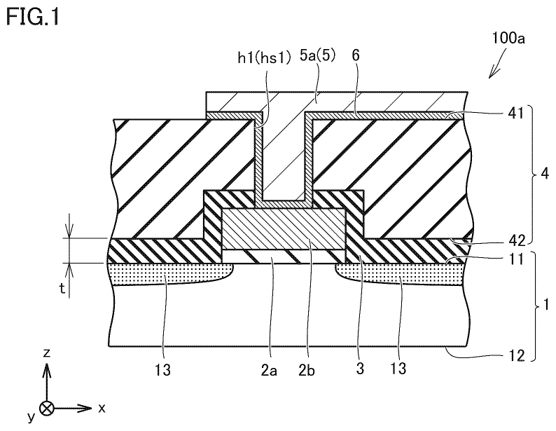

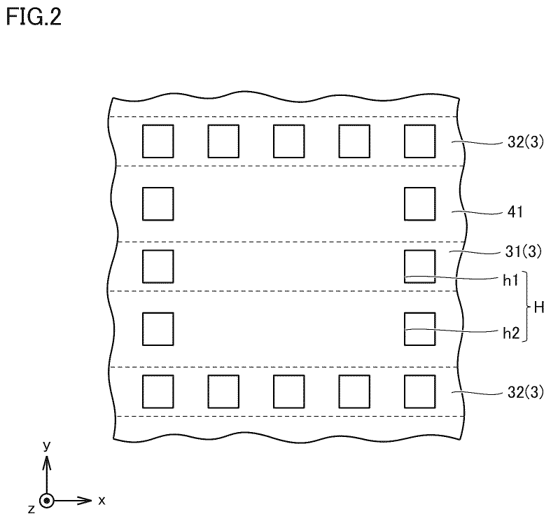

FIG. 1 is a schematic cross sectional view of a semiconductor device 100a in accordance with a first embodiment. FIG. 2 is a schematic plan view of semiconductor device 100a in accordance with the first embodiment.

Semiconductor device 100a shown in FIG. 1 is semiconductor device 100a for an integrated circuit (IC), for example, and mainly includes a semiconductor substrate 1, a gate insulating film 2a, a gate electrode 2b, a semiconductive insulating layer 3, an interlayer insulating layer 4, and an electric wire 5. It should be noted that electric wire 5 is not shown in FIG. 2. In FIG. 2, the outer shape of semiconductive insulating layer 3 is indicated by dotted lines.

As shown in FIG. 1, semiconductor substrate 1 has a first main surface 11 and a second main surface 12. Second main surface 12 is a surface located opposite to first main surface 11. Each of first main surface 11 and second main surface 12 extends in an x direction and in a y direction perpendicular to the x direction. A z direction is a thickness direction of semiconductor substrate 1. A normal direction of first main surface 11 is the z direction perpendicular to the x direction and the y direction. First main surface 11 faces a +z direction. Second main surface 12 faces a −z direction. A material constituting semiconductor substrate 1 is silicon, for example. The material constituting semiconductor substrate 1 may be a wide bandgap semiconductor substrate that is any one of silicon carbide (SiC), gallium nitride (GaN), and gallium oxide (Ga₂O₃), for example.

The concentration of an impurity contained in semiconductor substrate 1 may be adjusted according to the withstand voltage property of semiconductor device 100a. The conductivity type of semiconductor substrate 1 may be an n type, or may be a p type. A plurality of diffusion layers 13 are formed on first main surface 11. When the conductivity type of semiconductor substrate 1 is the n type, the conductivity type of diffusion layers 13 may be the p type. When the conductivity type of semiconductor substrate 1 is the p type, the conductivity type of diffusion layers 13 may be the n type. As shown in FIG. 1, on first main surface 11, the plurality of diffusion layers 13 are formed to be spaced from each other.

As shown in FIG. 1, gate insulating film 2a is formed on first main surface 11 of semiconductor substrate 1. In a plan view of first main surface 11, gate insulating film 2a is disposed at a position sandwiched between a pair of diffusion layers 13. In the plan view of first main surface 11, gate insulating film 2a partially overlaps diffusion layers 13. A material constituting gate insulating film 2a is silicon dioxide (SiO₂), for example.

As shown in FIG. 1, gate electrode 2b is formed on gate insulating film 2a. From a different viewpoint, gate electrode 2b is formed on semiconductor substrate 1 with gate insulating film 2a being interposed therebetween. A material constituting gate electrode 2b may be polysilicon, for example.

As shown in FIG. 1, semiconductive insulating layer 3 is formed on semiconductor substrate 1 to cover first main surface 11 and gate electrode 2b in the plan view of first main surface 11. Semiconductive insulating layer 3 does not have to be directly connected to gate electrode 2b. As described later, semiconductive insulating layer 3 may be formed on a front surface 41 of interlayer insulating layer 4, and may be disposed between front surface 41 and a first electric wire 5a in the z direction. Semiconductive insulating layer 3 may be formed to cover front surface 41 and first electric wire 5a in a plan view of front surface 41 of interlayer insulating layer 4. A material constituting semiconductive insulating layer 3 is a material including at least one of semi insulating silicon nitride (SInSiN) and silicon dioxide (SiO₂), for example. As described later, semiconductive insulating layer 3 is formed by plasma CVD (Chemical Vapor Deposition).

Semiconductive insulating layer 3 constituted by the material described above has a high insulation at low temperature, and has a high conductivity at high temperature. From a different viewpoint, electrical resistivity of semiconductive insulating layer 3 when semiconductive insulating layer 3 has a temperature of 27° C. (room temperature) is higher than electrical resistivity of semiconductive insulating layer 3 when semiconductive insulating layer 3 has a temperature of 150° C. Specifically, the electrical resistivity of semiconductive insulating layer 3 at room temperature (27° C.) may be about 1×10¹² Ωcm. The electrical resistivity of semiconductive insulating layer 3 at 150° C. may change from the electrical resistivity at room temperature (27° C.) to 1/1000 or less.

The electrical resistivity of semiconductive insulating layer 3 when semiconductive insulating layer 3 has a temperature of 27° C. may be more than or equal to 1×10¹¹ Ωcm and less than or equal to 1×10¹³ Ωcm. The electrical resistivity of semiconductive insulating layer 3 when semiconductive insulating layer 3 has a temperature of 150° C. may be less than or equal to 1×10¹⁰ Ωcm. Thus, the electrical resistivity of semiconductive insulating layer 3 has a temperature dependency, and changes reversibly according to the temperature of semiconductive insulating layer 3. That is, the electrical resistivity of semiconductive insulating layer 3 can be adjusted by adjusting the temperature of semiconductive insulating layer 3.

As shown in FIG. 1, interlayer insulating layer 4 is disposed on semiconductor substrate 1. Interlayer insulating layer 4 has front surface 41 and a back surface 42. Back surface 42 faces semiconductor substrate 1 and gate electrode 2b. In the first embodiment, back surface 42 of interlayer insulating layer 4 is connected to semiconductive insulating layer 3. Front surface 41 is a surface located opposite to back surface 42. A material constituting interlayer insulating layer 4 may be any one of silicon dioxide (SiO₂) and tetraethyl orthosilicate (TEOS), for example.

As shown in FIGS. 1 and 2, a plurality of contact holes H are formed in interlayer insulating layer 4. As shown in FIG. 2, contact holes H have a plurality of first contact holes h1 and a plurality of second contact holes h2. First contact hole h1 reaches gate electrode 2b from front surface 41. Second contact hole h2 reaches first main surface 11 of semiconductor substrate 1 from front surface 41. As shown in FIG. 2, first contact hole h1 and second contact hole h2 are disposed to be spaced from each other. From a different viewpoint, in front surface 41 of interlayer insulating layer 4, first contact hole h1 is disposed at a position where it overlaps gate electrode 2b. Second contact hole h2 is disposed at a position where it does not overlap gate electrode 2b.

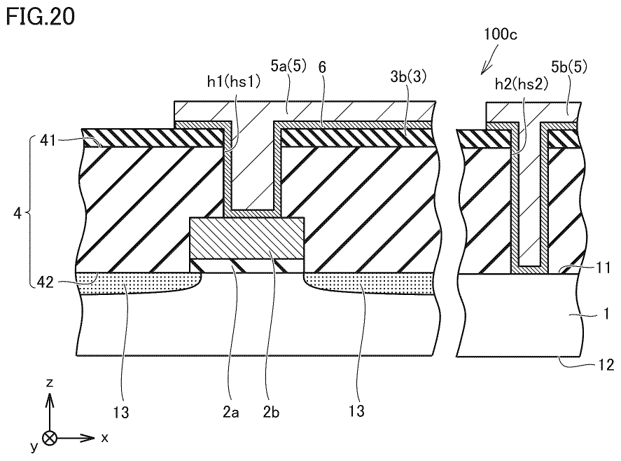

As shown in FIG. 1, electric wire 5 is formed to fill contact holes H. Electric wire 5 has first electric wire 5a and a second electric wire 5b (not shown). First electric wire 5a establishes conduction with gate electrode 2b. Second electric wire 5b establishes conduction with semiconductor substrate 1. First electric wire 5a is connected to gate electrode 2b, an inner circumferential surface hs1 of first contact hole h1, and front surface 41 of interlayer insulating layer 4, with a barrier metal 6 being interposed therebetween. Second electric wire 5b is connected to first main surface 11 of semiconductor substrate 1, an inner circumferential surface hs2 of second contact hole h2 (see FIG. 20), and front surface 41 of interlayer insulating layer 4, with barrier metal 6 being interposed therebetween.

By forming second contact hole h2 that reaches first main surface 11 of semiconductor substrate 1 from front surface 41, second electric wire 5b that establishes conduction with semiconductor substrate 1 can be formed. Thereby, more charges can be passed to semiconductor substrate 1. As a result, deterioration of gate insulating film 2a can be further suppressed as described later.

A material constituting electric wire 5 may be any metal, for example. Electric wire 5 may be a single layer, or may have a structure including a plurality of layers stacked in the z direction. Specifically, electric wire 5 is formed by depositing an aluminum alloy (for example, an Al—Si based alloy) on front surface 41 of interlayer insulating layer 4 and the inner circumferential surfaces of contact holes H, using PVD (Physical Vapor Deposition) such as sputtering and vapor deposition. A nickel alloy (a Ni alloy) may be formed on the aluminum alloy, using electroless plating or electrolytic plating. Electric wire 5 may be formed by stacking the aluminum alloy and the nickel alloy in this manner.

Electric wire 5 described above is formed on barrier metal 6. That is, barrier metal 6 is formed on a contact interface between electric wire 5 and interlayer insulating layer 4, on a contact interface between electric wire 5 and gate electrode 2b, and on a contact interface between electric wire 5 and semiconductor substrate 1. A material constituting barrier metal 6 is any one of titanium (Ti) and titanium nitride (TiN), for example.

Here, semiconductor device 100a in accordance with the first embodiment is characterized in that semiconductor device 100a includes semiconductive insulating layer 3 as shown in FIG. 1. Since semiconductive insulating layer 3 is formed, a charge generated during a process of manufacturing semiconductor device 100a can be passed to an outer circumferential portion (not shown) of semiconductor substrate 1 via semiconductive insulating layer 3. As a result, no charge is accumulated in gate insulating film 2a, and deterioration of gate insulating film 2a can be suppressed.

Further, the electrical resistivity of semiconductive insulating layer 3 has a temperature dependency. Accordingly, in a high temperature state such as during etching treatment and ion implantation treatment, semiconductive insulating layer 3 has a high conductivity. Thus, the charge generated during the process of manufacturing semiconductor device 100a can be passed to semiconductor substrate 1. On the other hand, at room temperature or at a temperature at which semiconductor device 100a is operated, semiconductive insulating layer 3 has a high insulation. Thus, there is no need to remove semiconductive insulating layer 3 during the process of manufacturing semiconductor device 100a, and semiconductive insulating layer 3 may remain after the manufacturing of semiconductor device 100a is completed. That is, since semiconductive insulating layer 3 remains without being removed until the manufacturing of semiconductor device 100a is completed, a charge can be passed to semiconductor substrate 1, for example when a process that involves a high temperature is performed, even after the ion implantation treatment is completed. As a result, no charge is accumulated in gate insulating film 2a, and deterioration of gate insulating film 2a can be suppressed.

The film formation range of semiconductive insulating layer 3 is not particularly limited, and semiconductive insulating layer 3 may be formed over entire first main surface 11 of semiconductor substrate 1. However, semiconductive insulating layer 3 has a high dielectric constant. Accordingly, if semiconductive insulating layer 3 is formed over entire first main surface 11 of semiconductor substrate 1, semiconductor device 100a may have an increased load capacity.

Semiconductive insulating layer 3 may be formed in a stripe shape as shown in FIG. 2. Semiconductive insulating layer 3 has a plurality of layers. In the plan view of first main surface 11, the plurality of layers are disposed to be spaced from each other in the y direction. Specifically, semiconductive insulating layer 3 may have a first layer 31 and a second layer 32. In the plan view of first main surface 11, first layer 31 and second layer 32 may be disposed to be spaced from each other in the y direction. Thereby, the charge can be passed to semiconductor substrate 1 while suppressing an increase in the load capacity of semiconductor device 100a. Further, a stress applied to semiconductor substrate 1 when semiconductive insulating layer 3 is formed in a stripe shape is smaller than a stress applied to semiconductor substrate 1 when semiconductive insulating layer 3 is formed over entire first main surface 11. As a result, warpage of semiconductor substrate 1 can be suppressed.

In the plan view of first main surface 11, semiconductive insulating layer 3 may be formed to extend to an end surface (not shown) that connects first main surface 11 and second main surface 12 of semiconductor substrate 1. Thereby, the charge can be passed from the end surface of semiconductor substrate 1. As a result, no charge is accumulated in gate insulating film 2a, and deterioration of gate insulating film 2a can be further suppressed.

As described above, semiconductive insulating layer 3 may be formed on semiconductor substrate 1 to cover first main surface 11 and gate electrode 2b in the plan view of first main surface 11. Thereby, the contact area between semiconductive insulating layer 3 and semiconductor substrate 1 increases, and more charges can be passed to semiconductor substrate 1. As a result, no charge is accumulated in gate insulating film 2a, and deterioration of gate insulating film 2a can be suppressed.

A thickness t of semiconductive insulating layer 3 in the z direction may be more than or equal to 50 nm. Thereby, control of film thickness in semiconductive insulating layer 3 is stabilized during the process of manufacturing semiconductor device 100a.

Thickness t of semiconductive insulating layer 3 in the z direction may be less than or equal to 100 nm. Thereby, an increase in the load capacity of semiconductor device 100a can be suppressed. Further, a stress applied to a foundation layer of semiconductive insulating layer 3 decreases, and occurrence of a crack in the foundation layer can be suppressed. Further, a stress applied to semiconductor substrate 1 decreases, and warpage of semiconductor substrate 1 can be suppressed. As a result, semiconductor device 100a can be stably manufactured.

### Method for Manufacturing Semiconductor Device

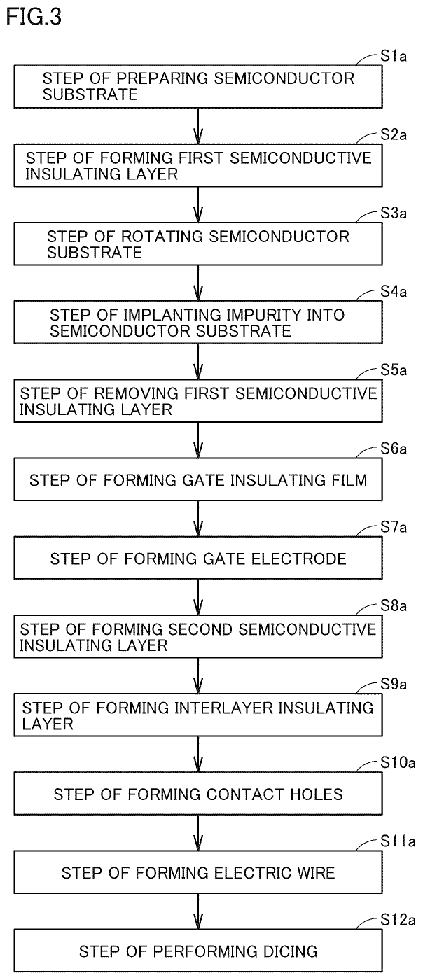

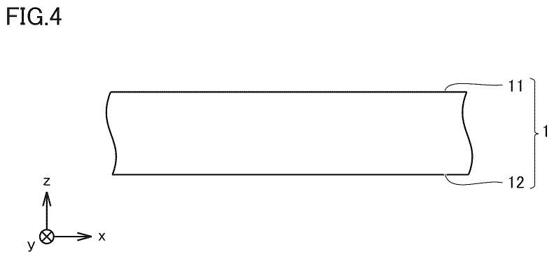

Hereinafter, a method for manufacturing semiconductor device 100a in the present embodiment will be described. FIG. 3 is a flowchart of the method for manufacturing semiconductor device 100a in accordance with the first embodiment. FIGS. 4 to 16 are each a schematic cross sectional view showing one step of the method for manufacturing semiconductor device 100a in accordance with the first embodiment.

First, the step of preparing semiconductor substrate 1 (S1a) is performed. In this step (S1a), as shown in FIG. 4, semiconductor substrate 1 as a silicon wafer which is a semiconductor material is prepared. The conductivity type of semiconductor substrate 1 may be the n type, or may be the p type. It should be noted that it is assumed that the conductivity type of semiconductor substrate 1 is the n type in the method for manufacturing semiconductor device 100a in accordance with the first embodiment.

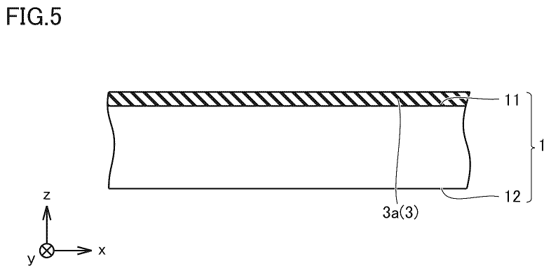

Then, the step of forming a first semiconductive insulating layer 3a (S2a) is performed. In this step (S2a), as shown in FIG. 5, first semiconductive insulating layer 3a is formed on semiconductor substrate 1. First semiconductive insulating layer 3a is formed by plasma CVD. A material constituting first semiconductive insulating layer 3a may be any material including at least one of semi insulating silicon nitride (SInSiN) and silicon dioxide (SiO₂), for example.

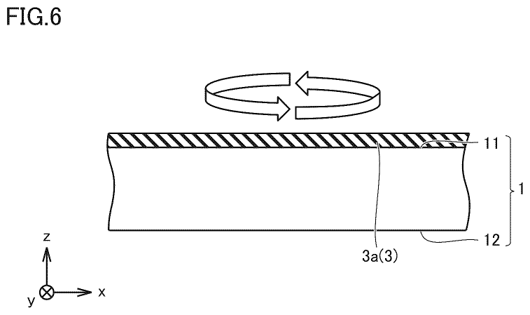

Then, the step of rotating semiconductor substrate 1 (S3a) is performed. In this step (S3a), as shown in FIG. 6, semiconductor substrate 1 is cleaned by rotating semiconductor substrate 1 while passing any one of gas and water. First semiconductive insulating layer 3a is charged by friction between a surface of semiconductor substrate 1 having first semiconductive insulating layer 3a formed thereon, and any one of the gas, the water, and an applied film. Conventionally, carbon dioxide (CO₂) is added to increase the conductivity of gas and suppress charging by a charge. In contrast, in the method for manufacturing semiconductor device 100a in accordance with the first embodiment, addition of carbon dioxide (CO₂) is not required in this step (S3a). That is, charging in first semiconductive insulating layer 3a can be suppressed without passing carbon dioxide (CO₂).

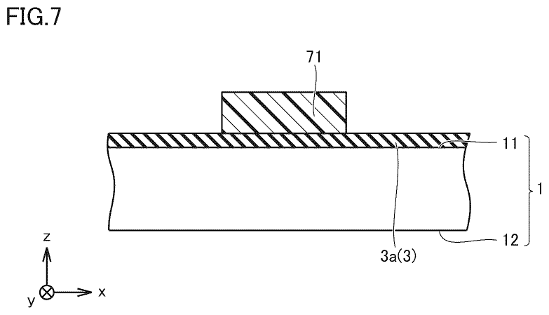

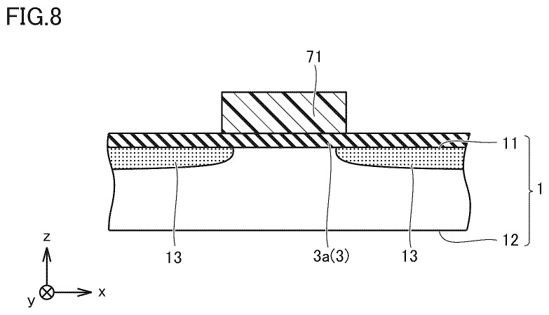

Then, the step of implanting an impurity into semiconductor substrate 1 (S4a) is performed. In this step (S4a), as shown in FIG. 7, a resist 71 is formed on first semiconductive insulating layer 3a. Thereafter, an impurity is implanted into semiconductor substrate 1. Thereby, as shown in FIG. 8, diffusion layers 13 are formed in first main surface 11 of semiconductor substrate 1. As shown in FIG. 8, in the plan view of first main surface 11, diffusion layers 13 are formed in regions where resist 71 is not formed. When the conductivity type of semiconductor substrate 1 is the n type, the conductivity type of diffusion layers 13 may be the p type. When the conductivity type of semiconductor substrate 1 is the p type, the conductivity type of diffusion layers 13 may be the n type. Also in this step, a charge caused by the step of implanting the impurity can be removed via first semiconductive insulating layer 3a.

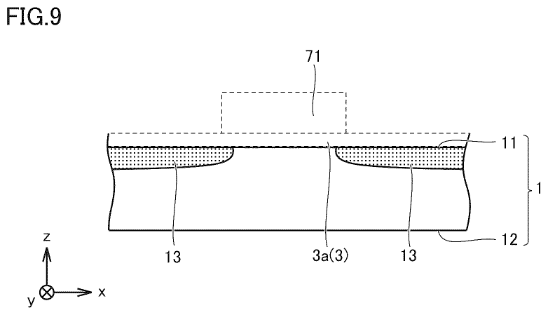

Then, the step of removing first semiconductive insulating layer 3a (S5a) is performed. In this step (S5a), as shown in FIG. 9, resist 71 and first semiconductive insulating layer 3a are removed by etching. It should be noted that, in this step (S5a), only resist 71 may be removed and first semiconductive insulating layer 3a do not have to be removed (not shown), as described later. When first semiconductive insulating layer 3a is not removed in this step (S5a), first semiconductive insulating layer 3a constitutes semiconductive insulating layer 3.

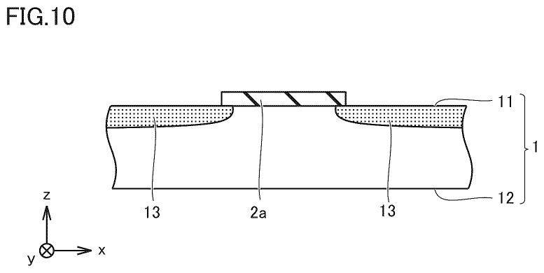

Then, the step of forming gate insulating film 2a (S6a) is performed. In this step (S6a), as shown in FIG. 10, gate insulating film 2a is formed on first main surface 11 by heating semiconductor substrate 1 under an atmosphere containing oxygen. The material constituting gate insulating film 2a is silicon dioxide (SiO₂), for example. It should be noted that, in order to secure insulation of gate insulating film 2a, first semiconductive insulating layer 3a located between gate insulating film 2a and first main surface 11 of semiconductor substrate 1 may be removed in the step of removing first semiconductive insulating layer 3a (S5a).

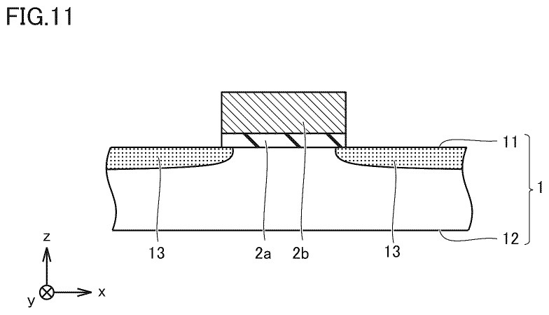

Then, the step of forming gate electrode 2b (S7a) is performed. In this step (S7a), as shown in FIG. 11, gate electrode 2b is formed by stacking polysilicon on gate insulating film 2a by CVD. The polysilicon is doped with an impurity having the n type or the p type.

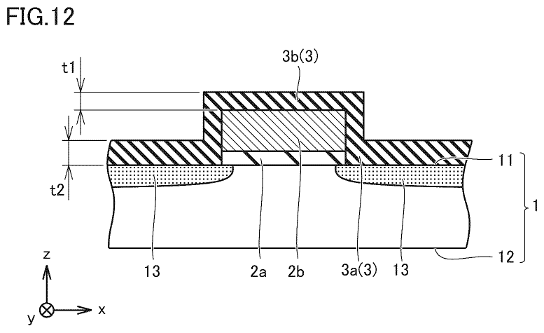

Then, the step of forming a second semiconductive insulating layer 3b (S8a) is performed. In this step (S8a), as shown in FIG. 12, second semiconductive insulating layer 3b is formed on semiconductor substrate 1. Second semiconductive insulating layer 3b is formed by plasma CVD. A material constituting second semiconductive insulating layer 3b may be the same as the material constituting first semiconductive insulating layer 3a, or may be different from the material constituting first semiconductive insulating layer 3a, for example.

Second semiconductive insulating layer 3b constitutes semiconductive insulating layer 3. When the step of removing first semiconductive insulating layer 3a (S5a) is not performed, semiconductive insulating layer 3 disposed between first main surface 11 of semiconductor substrate 1 and interlayer insulating layer 4 has a two-layer structure including first semiconductive insulating layer 3a and second semiconductive insulating layer 3b.

When the material constituting second semiconductive insulating layer 3b is the same as the material constituting first semiconductive insulating layer 3a, it is difficult to identify a boundary between first semiconductive insulating layer 3a and second semiconductive insulating layer 3b. As a result, semiconductive insulating layer 3 looks as a single-layer structure. However, a thickness t2 in the z direction of semiconductive insulating layer 3 disposed between first main surface 11 of semiconductor substrate 1 and interlayer insulating layer 4 is larger than a thickness t1 in the z direction of semiconductive insulating layer 3 disposed between gate electrode 2b and interlayer insulating layer 4. Accordingly, it is possible to determine whether or not semiconductive insulating layer 3 has a two-layer structure including first semiconductive insulating layer 3a and second semiconductive insulating layer 3b, by comparing thickness t2 in the z direction of semiconductive insulating layer 3 disposed between first main surface 11 of semiconductor substrate 1 and interlayer insulating layer 4, with thickness t1 in the z direction of semiconductive insulating layer 3 disposed between gate electrode 2b and interlayer insulating layer 4.

The thicknesses (t1 and t2) in the z direction of semiconductive insulating layer 3 may be more than or equal to 50 nm and less than or equal to 100 nm, for example.

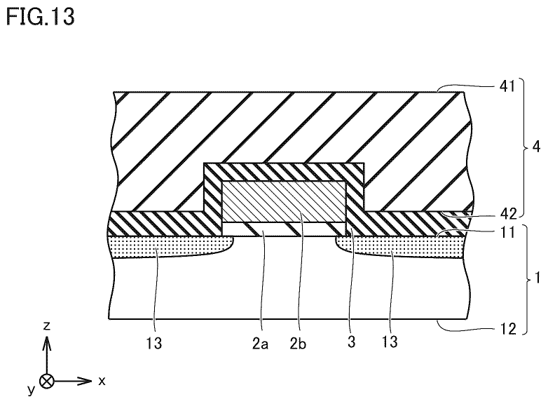

Then, the step of forming interlayer insulating layer 4 (S9a) is performed. In this step (S9a), as shown in FIG. 13, interlayer insulating layer 4 is formed on semiconductive insulating layer 3. The material constituting interlayer insulating layer 4 may be any one of silicon dioxide (SiO₂) and tetraethyl orthosilicate (TEOS), for example.

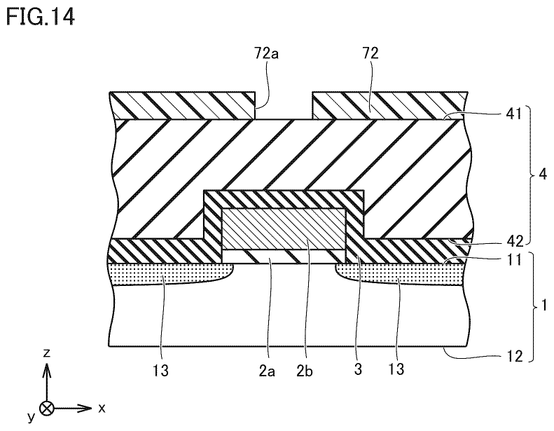

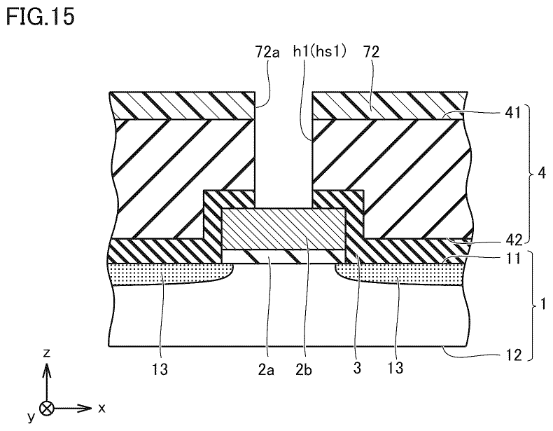

Then, the step of forming contact holes H (S10a) is performed. In this step (S10a), as shown in FIG. 14, a resist 72 is formed on front surface 41 of interlayer insulating layer 4. Resist 72 has an opening 72a. In the plan view of front surface 41, opening 72a is disposed at a position where it overlaps gate electrode 2b. By etching interlayer insulating layer 4 and semiconductive insulating layer 3 using resist 72 as a mask, first contact hole h1 is formed as shown in FIG. 15. First contact hole h1 reaches gate electrode 2b from front surface 41.

Although not shown, resist 72 may have an opening 72b (not shown). In the plan view of front surface 41, opening 72b is disposed at a position different from that of opening 72a. By etching interlayer insulating layer 4 and semiconductive insulating layer 3 using resist 72 as a mask, second contact hole h2 (not shown) is formed. Second contact hole h2 reaches first main surface 11 of semiconductor substrate 1 from front surface 41. Thereafter, resist 72 is removed.

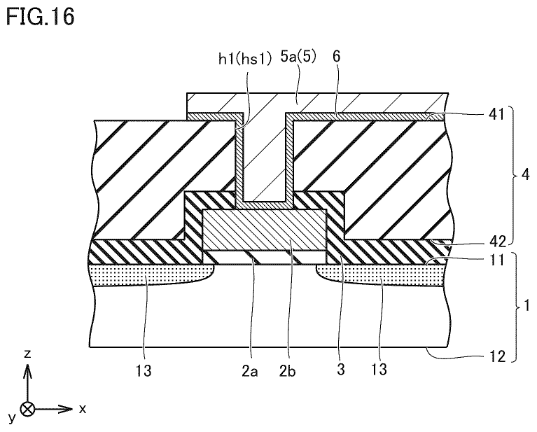

Then, the step of forming electric wire 5 (S11a) is performed. In this step (S11a), as shown in FIG. 16, electric wire 5 is formed to fill contact holes H. First electric wire 5a is connected to gate electrode 2b, inner circumferential surface hs1 of first contact hole h1, and front surface 41 of interlayer insulating layer 4, with barrier metal 6 being interposed therebetween. Although not shown, second electric wire 5b is connected to first main surface 11 of semiconductor substrate 1, inner circumferential surface hs2 of second contact hole h2, and front surface 41 of interlayer insulating layer 4, with barrier metal 6 being interposed therebetween.

The material constituting electric wire 5 may be any metal, for example. Electric wire 5 may be a single layer, or may have a structure including a plurality of layers stacked in the z direction. Specifically, electric wire 5 is formed by stacking an aluminum alloy (for example, an Al—Si based alloy) on front surface 41 of interlayer insulating layer 4 and the inner circumferential surfaces of contact holes H, using PVD (Physical Vapor Deposition) such as sputtering and vapor deposition. A nickel alloy (a Ni alloy) may be formed on the aluminum alloy, using electroless plating or electrolytic plating. Electric wire 5 may be formed by stacking the aluminum alloy and the nickel alloy in this manner.

By using plating, it is easy to form thick electric wire 5. Accordingly, by forming thick electric wire 5, heat capacity of electric wire 5 increases, and thus heat resistance of semiconductor device 100a is improved.

Electric wire 5 described above is formed on barrier metal 6. That is, barrier metal 6 is formed on the contact interface between electric wire 5 and interlayer insulating layer 4, on the contact interface between electric wire 5 and gate electrode 2b, and on the contact interface between electric wire 5 and semiconductor substrate 1. The material constituting barrier metal 6 is any one of titanium (Ti) and titanium nitride (TiN), for example.

Thickness t of semiconductive insulating layer 3 in the z direction may be less than or equal to 100 nm.

Then, the step of performing dicing (S12a) is performed. In this step (S12a), by dicing semiconductor substrate 1 using any one of laser dicing or blade dicing, semiconductor device 100a shown in FIG. 1 is manufactured. By cutting semiconductor substrate 1 in a matrix shape, a plurality of semiconductor devices 100a are manufactured.

Thereby, the charge generated during the process of manufacturing semiconductor device 100a can be passed to the outer circumferential portion of semiconductor substrate 1 via semiconductive insulating layer 3. Specifically, during the process of manufacturing semiconductor device 100a, charging of first semiconductive insulating layer 3a by the friction between first main surface 11 of semiconductor substrate 1 and any one of the gas, the water, and the applied film in the step of rotating semiconductor substrate 1 (S3a), and charging by an ion beam in the step of implanting the impurity into semiconductor substrate 1 (S4a), that is, charging by a positive charge generated by passing positive ions from the ion beam to semiconductor substrate 1, are suppressed. Further, addition of carbon dioxide (CO₂) is not required in the step of rotating semiconductor substrate 1 (S3a).

As a result, it is possible to obtain semiconductor device 100a in which no charge is accumulated in gate insulating film 2a and deterioration of gate insulating film 2a is suppressed.

Further, the electrical resistivity of semiconductive insulating layer 3 has a temperature dependency. Accordingly, in a high temperature state such as during etching treatment and ion implantation treatment, semiconductive insulating layer 3 has a high conductivity. Thus, the charge generated during the process of manufacturing semiconductor device 100a can be passed to semiconductor substrate 1. On the other hand, in a low temperature state at a relatively low temperature such as room temperature or a temperature at which semiconductor device 100a is operated, semiconductive insulating layer 3 has a high insulation. Thus, there is no need to remove semiconductive insulating layer 3 during the process of manufacturing semiconductor device 100a, and semiconductive insulating layer 3 may remain after the manufacturing of semiconductor device 100a is completed.

### Function and Effect

Semiconductor device 100a according to the present disclosure includes semiconductor substrate 1, gate insulating film 2a, gate electrode 2b, first electric wire 5a, and semiconductive insulating layer 3. Gate insulating film 2a is formed on semiconductor substrate 1. Gate electrode 2b is formed on semiconductor substrate 1 with gate insulating film 2a being interposed therebetween. First electric wire 5a is connected to gate electrode 2b. Semiconductive insulating layer 3 is connected to at least one of gate electrode 2b and first electric wire 5a.

Thereby, the charge generated during the process of manufacturing semiconductor device 100a can be passed to the outer circumferential portion of semiconductor substrate 1 via semiconductive insulating layer 3. Specifically, during the process of manufacturing semiconductor device 100a, charging of first semiconductive insulating layer 3a by the friction between first main surface 11 of semiconductor substrate 1 and any one of the gas, the water, and the applied film in the step of rotating semiconductor substrate 1 (S3a), charging by an ion beam in the step of implanting the impurity into semiconductor substrate 1 (S4a), and the like are suppressed. Further, addition of carbon dioxide (CO₂) is not required in the step of rotating semiconductor substrate 1 (S3a). As a result, it is possible to obtain semiconductor device 100a in which no charge is accumulated in gate insulating film 2a and deterioration of gate insulating film 2a is suppressed.

Further, the electrical resistivity of semiconductive insulating layer 3 has a temperature dependency. Accordingly, in a high temperature state such as during etching treatment and ion implantation treatment, semiconductive insulating layer 3 has a high conductivity. Thus, the charge generated during the process of manufacturing semiconductor device 100a can be passed to semiconductor substrate 1. On the other hand, in a low temperature state such as at room temperature or when semiconductor device 100a is operated, semiconductive insulating layer 3 has a high insulation. Thus, there is no need to remove semiconductive insulating layer 3 during the process of manufacturing semiconductor device 100a, and semiconductive insulating layer 3 may remain after the manufacturing of semiconductor device 100a is completed.

In semiconductor device 100a, the electrical resistivity of semiconductive insulating layer 3 when semiconductive insulating layer 3 has a temperature of 27° C. is higher than the electrical resistivity of semiconductive insulating layer 3 when semiconductive insulating layer 3 has a temperature of 150° C.

Thereby, during the process of manufacturing semiconductor device 100a, semiconductive insulating layer 3 has a high conductivity. Thus, the charge generated during the process of manufacturing semiconductor device 100a can be passed to semiconductor substrate 1. On the other hand, in a low temperature state such as when semiconductor device 100a is operated, semiconductive insulating layer 3 has a high insulation. Thus, there is no need to remove semiconductive insulating layer 3 during the process of manufacturing semiconductor device 100a, and semiconductive insulating layer 3 may remain after the manufacturing of semiconductor device 100a is completed.

In semiconductor device 100a, the electrical resistivity of semiconductive insulating layer 3 when semiconductive insulating layer 3 has a temperature of 27° C. is more than or equal to 1×10¹¹ Ωcm and less than or equal to 1×10¹³ Ωcm.

Thereby, in a room temperature state such as when semiconductor device 100a is operated, semiconductive insulating layer 3 has a high insulation. Thus, there is no need to remove semiconductive insulating layer 3 during the process of manufacturing semiconductor device 100a, and semiconductive insulating layer 3 may remain after the manufacturing of semiconductor device 100a is completed.

In semiconductor device 100a, the electrical resistivity of semiconductive insulating layer 3 when semiconductive insulating layer 3 has a temperature of 150° C. is less than or equal to 1×10¹⁰ Ωcm.

Thereby, during the process of manufacturing semiconductor device 100a, semiconductive insulating layer 3 may have a high conductivity. Thus, the charge generated during the process of manufacturing semiconductor device 100a can be passed to semiconductor substrate 1.

In semiconductor device 100a, the material constituting semiconductive insulating layer 3 includes at least one of semi insulating silicon nitride and silicon dioxide.

Thereby, during the process of manufacturing semiconductor device 100a, semiconductive insulating layer 3 may have a high conductivity. Thus, the charge generated during the process of manufacturing semiconductor device 100a can be passed to semiconductor substrate 1. On the other hand, in a low temperature state such as when semiconductor device 100a is operated, semiconductive insulating layer 3 has a high insulation. Thus, there is no need to remove semiconductive insulating layer 3 during the process of manufacturing semiconductor device 100a, and semiconductive insulating layer 3 may remain after the manufacturing of semiconductor device 100a is completed.

In semiconductor device 100a, semiconductive insulating layer 3 has thickness t of more than or equal to 50 nm and less than or equal to 100 nm.

Thereby, control of film thickness in semiconductive insulating layer 3 is stabilized during the process of manufacturing semiconductor device 100a. Further, an increase in the load capacity of semiconductor device 100a can be suppressed. Further, the stress applied to the foundation layer of semiconductive insulating layer 3 decreases, and occurrence of a crack in the foundation layer can be suppressed. Further, the stress applied to semiconductor substrate 1 decreases, and warpage of semiconductor substrate 1 can be suppressed. As a result, semiconductor device 100a can be stably manufactured.

Semiconductor device 100a further includes interlayer insulating layer 4. Interlayer insulating layer 4 is disposed on semiconductor substrate 1. Interlayer insulating layer 4 has front surface 41. Front surface 41 is located opposite to a surface that faces semiconductor substrate 1 and gate electrode 2b. First contact hole h1 is formed in interlayer insulating layer 4. First contact hole h1 reaches gate electrode 2b from front surface 41. First electric wire 5a is connected to inner circumferential surface hs1 of first contact hole h1 and front surface 41.

Thereby, the charge generated during the process of manufacturing semiconductor device 100a can be passed to the outer circumferential portion of semiconductor substrate 1 via semiconductive insulating layer 3. As a result, it is possible to obtain semiconductor device 100a in which no charge is accumulated in gate insulating film 2a and deterioration of gate insulating film 2a is suppressed.

In semiconductor device 100a, semiconductive insulating layer 3 has first layer 31 and second layer 32. In a plan view of semiconductor substrate 1, first layer 31 and second layer 32 are disposed to be spaced from each other.

Thereby, the charge can be passed to semiconductor substrate 1 while suppressing an increase in the load capacity of semiconductor device 100a. Further, the stress applied to semiconductor substrate 1 when semiconductive insulating layer 3 is formed in a stripe shape is smaller than the stress applied to semiconductor substrate 1 when semiconductive insulating layer 3 is formed over entire first main surface 11. As a result, warpage of semiconductor substrate 1 can be suppressed.

A method for manufacturing semiconductor device 100a according to the present disclosure includes the step of preparing semiconductor substrate 1 (S1a), the step of forming first semiconductive insulating layer 3a on semiconductor substrate 1 (S2a), and the step of rotating semiconductor substrate 1 (S3a) after the step of forming first semiconductive insulating layer 3a (S2a).

Thereby, the charge generated during the process of manufacturing semiconductor device 100a can be passed to the outer circumferential portion of semiconductor substrate 1 via semiconductive insulating layer 3. Specifically, charging of first semiconductive insulating layer 3a by the friction between the surface of semiconductor substrate 1 having first semiconductive insulating layer 3a formed thereon, and any one of the gas, the water, and the applied film in the step of rotating semiconductor substrate 1 (S3a) is suppressed. Further, addition of carbon dioxide (CO₂) to the gas is not required in the step of rotating semiconductor substrate 1 (S3a). As a result, it is possible to obtain semiconductor device 100a in which no charge is accumulated in gate insulating film 2a and deterioration of gate insulating film 2a is suppressed.

The method for manufacturing semiconductor device 100a further includes the step of implanting an impurity into semiconductor substrate 1 (S4a) after the step of forming first semiconductive insulating layer 3a (S2a), the step of removing first semiconductive insulating layer 3a (S5a) after the step of implanting the impurity (S4a), the step of forming gate electrode 2b on semiconductor substrate 1 (S7a) after the step of removing first semiconductive insulating layer 3a (S5a), and the step of forming second semiconductive insulating layer 3b to cover gate electrode 2b (S8a) after the step of forming gate electrode 2b (S7a).

Thereby, the charge generated during the process of manufacturing semiconductor device 100a can be passed to the outer circumferential portion of semiconductor substrate 1 via semiconductive insulating layer 3. Specifically, charging by an ion beam in the step of implanting the impurity into semiconductor substrate 1 (S4a) and the like are suppressed. As a result, it is possible to obtain semiconductor device 100a in which no charge is accumulated in gate insulating film 2a and deterioration of gate insulating film 2a is suppressed.

### Second Embodiment

### Configuration of Semiconductor Device

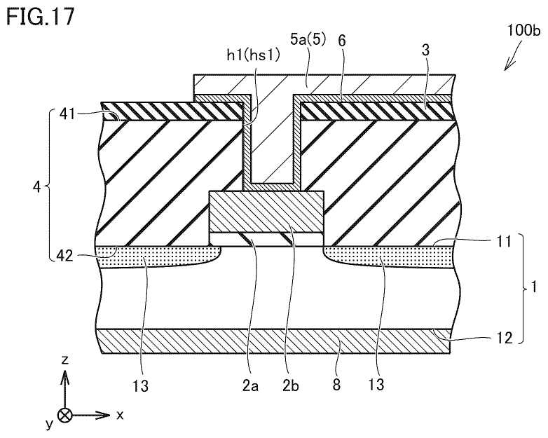

FIG. 17 is a schematic cross sectional view of a semiconductor device 100b in accordance with a second embodiment. FIG. 17 corresponds to FIG. 1. Semiconductor device 100b shown in FIG. 17 has basically the same configuration as that of semiconductor device 100a shown in FIG. 1, and has a difference in that it is not semiconductor device 100a for an integrated circuit but is semiconductor device 100b for a power semiconductor. When semiconductor device 100b is for a power semiconductor, a drain electrode 8 may be formed on second main surface 12 of semiconductor substrate 1, if needed.

A material constituting drain electrode 8 may include at least one of an aluminum-silicon alloy, titanium, nickel, and gold, for example. Drain electrode 8 may be formed by stacking a plurality of metals such as an aluminum-silicon alloy, titanium, nickel, and gold. Further, on a metal film formed by PVD, a metal film may be further formed by electroless plating or electrolytic plating. Drain electrode 8 may be formed by stacking the metal film formed by PVD and the metal film formed by electroless plating or electrolytic plating in this manner.

Semiconductive insulating layer 3 may be formed on front surface 41 of interlayer insulating layer 4. From a different viewpoint, as shown in FIG. 17, semiconductive insulating layer 3 may be disposed at a position sandwiched between first electric wire 5a and interlayer insulating layer 4 in the z direction.

### Method for Manufacturing Semiconductor Device

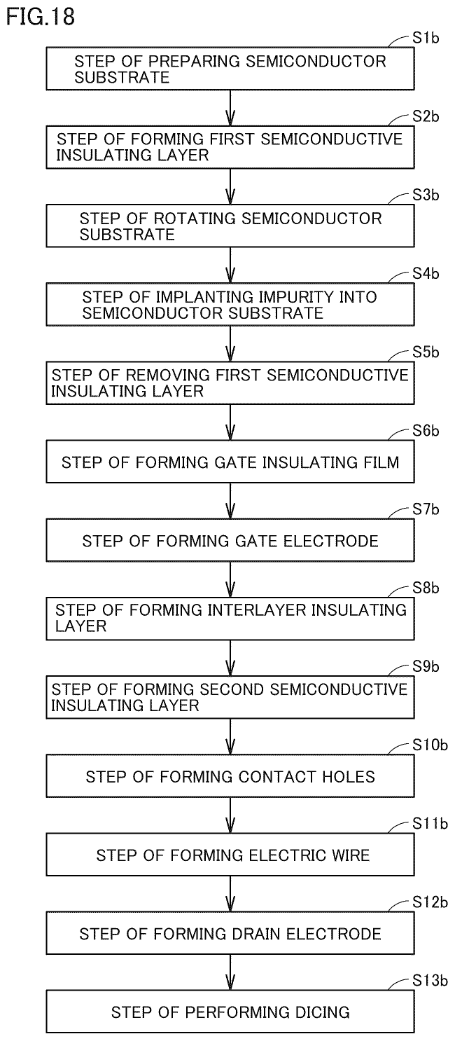

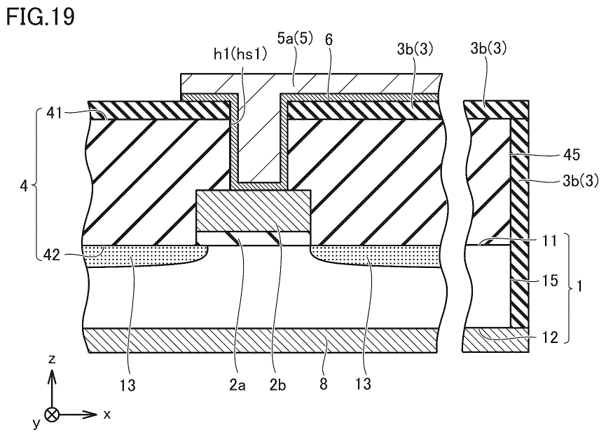

Hereinafter, a method for manufacturing semiconductor device 100b in the present embodiment will be described. FIG. 18 is a flowchart of the method for manufacturing semiconductor device 100b in accordance with the second embodiment. FIG. 19 is a schematic cross sectional view showing one step of the method for manufacturing semiconductor device 100b in accordance with the second embodiment. First, the same steps as the steps shown in FIGS. 4 to 11 in the method for manufacturing semiconductor device 100a in accordance with the first embodiment are performed. That is, the steps of preparing semiconductor substrate 1 (S1b) to forming gate electrode 2b (S7b) are performed.

Then, the step of forming interlayer insulating layer 4 (S8b) is performed. Specifically, interlayer insulating layer 4 is formed to cover first main surface 11 of semiconductor substrate 1 and gate electrode 2b. That is, back surface 42 of interlayer insulating layer 4 is connected to first main surface 11 and gate electrode 2b.

Then, the step of forming second semiconductive insulating layer 3b (S9b) is performed. Specifically, second semiconductive insulating layer 3b is formed to cover front surface 41 of interlayer insulating layer 4. Second semiconductive insulating layer 3b may be formed on an end surface 45 that connects front surface 41 and back surface 42 of interlayer insulating layer 4, and on an end surface 15 that connects first main surface 11 and second main surface 12 of semiconductor substrate 1 (see FIG. 19). The shape of semiconductive insulating layer 3 may be a stripe shape in which a plurality of layers are disposed to be spaced from each other in the y direction in the plan view of front surface 41. Each of the plurality of layers may be formed on end surface 45 of interlayer insulating layer 4 and on end surface 15 of semiconductor substrate 1.

Then, the step of forming contact holes H (S10b) is performed. In this step (S10b), resist 72 is formed on second semiconductive insulating layer 3b. Resist 72 has opening 72a. In the plan view of front surface 41, opening 72a is disposed at a position where it overlaps gate electrode 2b. By etching interlayer insulating layer 4 and semiconductive insulating layer 3 using resist 72 as a mask, first contact hole h1 is formed. First contact hole h1 reaches gate electrode 2b from front surface 41.

When second semiconductive insulating layer 3b is formed on end surface 45 of interlayer insulating layer 4 and on end surface 15 of semiconductor substrate 1 as shown in FIG. 19 in the step of forming second semiconductive insulating layer 3b (S9b), second contact hole h2 that reaches first main surface 11 of semiconductor substrate 1 from an upper surface of semiconductive insulating layer 3 does not have to be formed, as described later.

Then, the step of forming electric wire 5 (S11b) is performed. In this step (S11b), electric wire 5 is formed to fill contact holes H. First electric wire 5a is connected to gate electrode 2b, inner circumferential surface hs1 of first contact hole h1, and an upper surface of second semiconductive insulating layer 3b, with barrier metal 6 being interposed therebetween.

The material constituting electric wire 5 may be any metal, for example. Electric wire 5 may be a single layer, or may have a structure including a plurality of layers stacked in the z direction. Specifically, electric wire 5 is formed by depositing an aluminum alloy (for example, an Al—Si based alloy) on front surface 41 of interlayer insulating layer 4 and the inner circumferential surfaces of contact holes H, using PVD (Physical Vapor Deposition) such as sputtering and vapor deposition. A nickel alloy (a Ni alloy) may be formed on the aluminum alloy, using electroless plating or electrolytic plating. Electric wire 5 may be formed by stacking the aluminum alloy and the nickel alloy in this manner.

By using plating, it is easy to form thick electric wire 5. Accordingly, by forming thick electric wire 5, heat capacity of electric wire 5 increases, and thus heat resistance of semiconductor device 100b is improved.

Formation of the nickel alloy using plating may be performed after the step of forming drain electrode 8 (S12b) described later.

Then, the step of forming drain electrode 8 (S12b) is performed. In this step (S12b), as shown in FIG. 19, drain electrode 8 is formed on second main surface 12 of semiconductor substrate 1. This step (S12b) is performed when semiconductor device 100b is manufactured as a semiconductor device for a power semiconductor. Drain electrode 8 is formed by depositing an aluminum-silicon alloy, titanium, or the like on second main surface 12 by PVD such as sputtering or vapor deposition, for example.

Second semiconductive insulating layer 3b is connected to drain electrode 8. Thereby, a charge can be passed to drain electrode 8 also in semiconductor device 100b in which second contact hole h2 connected to semiconductor substrate 1 is not formed.

The material constituting drain electrode 8 may include at least one of an aluminum-silicon alloy, titanium, nickel, and gold, for example. Drain electrode 8 may be formed by stacking a plurality of metals such as an aluminum-silicon alloy, titanium, nickel, and gold. Further, on a metal film formed by PVD, a metal film may be further formed by electroless plating or electrolytic plating. Drain electrode 8 may be formed by stacking the metal film formed by PVD and the metal film formed by electroless plating or electrolytic plating in this manner.

Then, the step of performing dicing (S13b) is performed. Thereby, semiconductor device 100b in accordance with the second embodiment as shown in FIG. 17 is manufactured.

### Third Embodiment

### Configuration of Semiconductor Device

FIG. 20 is a schematic cross sectional view of a semiconductor device 100c in accordance with a third embodiment. FIG. 20 corresponds to FIG. 1. Semiconductor device 100c shown in FIG. 20 has basically the same configuration as that of semiconductor device 100a shown in FIG. 1, and has a difference in that semiconductive insulating layer 3 is formed on front surface 41 of interlayer insulating layer 4. Semiconductive insulating layer 3 is not directly connected to semiconductor substrate 1. Accordingly, second contact hole h2 that reaches first main surface 11 of semiconductor substrate 1 from the upper surface of semiconductive insulating layer 3 is formed. Specifically, as shown in FIG. 20, first contact hole h1 and second contact hole h2 are disposed to be spaced from each other.

Second electric wire 5b establishes conduction with semiconductor substrate 1. Second electric wire 5b is connected to first main surface 11 of semiconductor substrate 1, inner circumferential surface hs2 of second contact hole h2, and the upper surface of semiconductive insulating layer 3, with barrier metal 6 being interposed therebetween.

When semiconductive insulating layer 3 is formed on front surface 41 of interlayer insulating layer 4, second electric wire 5b that establishes conduction with semiconductor substrate 1 can be formed by forming second contact hole h2 that reaches first main surface 11 of semiconductor substrate 1 from the upper surface of semiconductive insulating layer 3. Thereby, a charge can be passed to semiconductor substrate 1. As a result, deterioration of gate insulating film 2a can be further suppressed.

### Function and Effect

In semiconductor device 100c, semiconductive insulating layer 3 is connected to first electric wire 5a and front surface 41.

Thereby, the charge generated during the process of manufacturing semiconductor device 100c can be passed to the outer circumferential portion of semiconductor substrate 1 via semiconductive insulating layer 3. As a result, it is possible to obtain semiconductor device 100c in which no charge is accumulated in gate insulating film 2a and deterioration of gate insulating film 2a is suppressed.

Semiconductor device 100c further includes second electric wire 5b. Second electric wire 5b is connected to semiconductive insulating layer 3. Second contact hole h2 is formed in interlayer insulating layer 4. Second contact hole h2 reaches semiconductor substrate 1 from front surface 41. Second electric wire 5b is connected to inner circumferential surface hs2 of second contact hole h2 and front surface 41.

Thereby, the charge generated during the process of manufacturing semiconductor device 100c can be passed to the outer circumferential portion of semiconductor substrate 1 via semiconductive insulating layer 3. As a result, it is possible to obtain semiconductor device 100c in which no charge is accumulated in gate insulating film 2a and deterioration of gate insulating film 2a is suppressed.

### Fourth Embodiment

### Configuration of Semiconductor Device

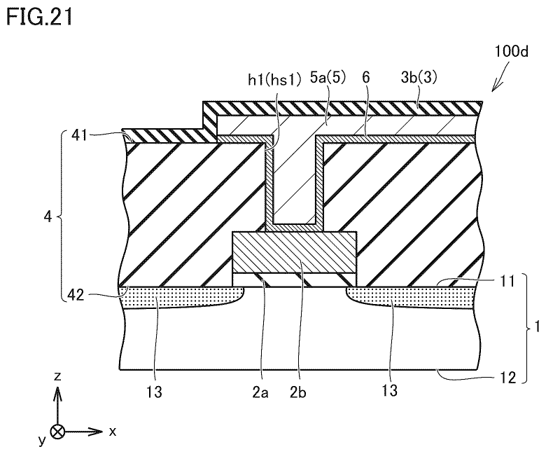

FIG. 21 is a schematic cross sectional view of a semiconductor device 100d in accordance with a fourth embodiment. FIG. 21 corresponds to FIG. 1.

Semiconductor device 100d shown in FIG. 21 has basically the same configuration as that of semiconductor device 100a shown in FIG. 1, and has a difference in that semiconductive insulating layer 3 is formed to cover front surface 41 and first electric wire 5a in the plan view of front surface 41 of interlayer insulating layer 4. Thereby, a portion of charge can be passed from an upper surface of first electric wire 5a to the outside. As a result, deterioration of gate insulating film 2a can be further suppressed.

It should be understood that the embodiments disclosed herein are illustrative and non-restrictive in every respect. At least two of the embodiments disclosed herein may be combined, unless they are inconsistent. The basic scope of the present disclosure is defined by the scope of the claims, rather than the description above, and is intended to include any modifications within the scope and meaning equivalent to the scope of the claims.

What is claimed is:

1. A semiconductor device comprising:
a semiconductor substrate;
a gate insulating film formed on the semiconductor substrate;
a gate electrode formed on the semiconductor substrate with the gate insulating film being interposed therebetween;
a first electric wire connected to the gate electrode; and
a semiconductive insulating layer connected to at least one of the gate electrode and the first electric wire.

2. The semiconductor device according to claim 1, wherein electrical resistivity of the semiconductive insulating layer when the semiconductive insulating layer has a temperature of 27° C. is higher than electrical resistivity of the semiconductive insulating layer when the semiconductive insulating layer has a temperature of 150° C.

3. The semiconductor device according to claim 2, wherein the electrical resistivity of the semiconductive insulating layer when the semiconductive insulating layer has a temperature of 27° C. is more than or equal to 1×10¹¹ Ωcm and less than or equal to 1×10¹³ Ωcm.

4. The semiconductor device according to claim 3, wherein the electrical resistivity of the semiconductive insulating layer when the semiconductive insulating layer has a temperature of 150° C. is less than or equal to 1×10¹⁰ Ωcm.

5. The semiconductor device according to claim 1, wherein a material constituting the semiconductive insulating layer includes at least one of semi insulating silicon nitride and silicon dioxide.

6. The semiconductor device according to claim 1, wherein the semiconductive insulating layer has a thickness of more than or equal to 50 nm and less than or equal to 100 nm.

7. The semiconductor device according to claim 1, further comprising an interlayer insulating layer disposed on the semiconductor substrate, wherein
the interlayer insulating layer has a front surface located opposite to a surface that faces the semiconductor substrate and the gate electrode,
a first contact hole that reaches the gate electrode from the front surface is formed in the interlayer insulating layer, and
the first electric wire is connected to an inner circumferential surface of the first contact hole and the front surface.

8. The semiconductor device according to claim 7, wherein the semiconductive insulating layer is connected to the first electric wire and the front surface.

9. The semiconductor device according to claim 7, further comprising a second electric wire connected to the semiconductive insulating layer, wherein
a second contact hole that reaches the semiconductor substrate from the front surface is formed in the interlayer insulating layer, and
the second electric wire is connected to an inner circumferential surface of the second contact hole and the front surface.

10. The semiconductor device according to claim 1, wherein
the semiconductive insulating layer has a first layer and a second layer, and
in a plan view of the semiconductor substrate, the first layer and the second layer are disposed to be spaced from each other.

11. A method for manufacturing a semiconductor device, the method comprising:
preparing a semiconductor substrate;
forming a first semiconductive insulating layer on the semiconductor substrate; and
rotating the semiconductor substrate after forming the first semiconductive insulating layer.

12. The method for manufacturing the semiconductor device according to claim 11, further comprising:
implanting an impurity into the semiconductor substrate after forming the first semiconductive insulating layer;
removing the first semiconductive insulating layer after implanting the impurity;
forming a gate electrode on the semiconductor substrate after removing the first semiconductive insulating layer; and
forming a second semiconductive insulating layer to cover the gate electrode after forming the gate electrode.
